(19) United States
(12) Patent Application Publication
(10) Pub. No.: US 2015/0349493 A1
(43) Pub. Date: Dec. 3, 2015

(54) SEMICONDUCTOR LASER WITH EXTERNAL CAVITY HAVING NON-STRAIGHT WAVEGUIDE

(71) Applicant: PHOVEL.CO.LTD., Daejeon (KR)

(72) Inventor: Jeong-Soo KIM, Gongju-si (KR)

(21) Appl. No.: 14/540,340

(22) Filed: Nov. 13, 2014

(30) Foreign Application Priority Data
May 30, 2014 (KR) 10-2014-0066258

(51) Int. Cl. H01S 5/14; H01S 5/026; H01S 5/0687; H01S 5/022

(52) U.S. Cl. CPC H01S 5/146; H01S 5/02212; H01S 5/02252; H01S 5/0261; H01S 5/141; H01S 5/0687

(57) ABSTRACT

The present invention relates to a semiconductor laser with an external cavity having a non-straight waveguide, in which a semiconductor laser diode used as an optical gain medium has a nonreflective coated side, light emitted from the laser diode chip is collected to a waveguide type of waveguide-selective filter and light having a wavelength selected by a grating on the waveguide is fed back to the laser diode chip, and the wavelength of emitted light is changed by electrically or thermally changing the properties of the waveguide.

A laser with an external cavity having a non-straight waveguide according to the present invention is formed in a TO-can type package, in which a semiconductor laser diode chip and a waveguide with a grating are disposed, the wavelength of light from the semiconductor laser is determined by the grating of the waveguide, and an exit surface and an incident surface of the waveguide are formed in the same direction

### CROSS-REFERENCE TO RELATED APPLICATIONS

This application claims the priority of Korean Patent Application No. 10-2014-0066258 filed on May 30, 2014, in the Korean Intellectual Property Office, the disclosure of which is incorporated herein by reference.

### BACKGROUND OF THE INVENTION

1. Field of the Invention

The present invention relates to a semiconductor laser with a wavelength tunable external cavity, and more particularly, to a semiconductor laser with an external cavity having a non-straight waveguide, in which a semiconductor laser diode chip used as an optical gain medium has a nonreflective coated side, light emitted from the laser diode chip is focused to a waveguide type of waveguide-selective filter and light having a wavelength selected by a grating on the waveguide is fed back to the laser diode chip, and the wavelength of emitted light is changed by electrically or thermally changing the properties of the waveguide.

2. Description of the Related Art

Recently, optical communication has been widely used as a method of transmission a great amount of information. Optical communication is used not only for information communication among countries, but for communication of a large amount of information among homes through direct optical relay in the type of FTTH (Fiber To The Home) or FTTP (Fiber To The Pole). The optical communication for a large amount of information requires a light emitting device that generates light for the optical communication, an optical fiber that is a medium carrying an optical signal, and a light receiving element that converts a transmitted optical signal into an electric signal. For the light emitting device generating light for the optical communication, a laser diode using a semiconductor device manufacturing technique is used. The laser diode is a device that converts an electric signal into optical signal.

A semiconductor laser diode includes a waveguide that is set in a gain medium converting electricity into light and determines directivity of the light and reflective mirrors that can feedback light. A fabry-perot (hereafter, abbreviated to ‘FP’) type laser diode, the simplest semiconductor laser diode, uses both ends of a gain medium as reflective mirrors. The part in which light reflects and resonates is called a cavity and light resonates between both ends of common semiconductor laser diode chips, so the ends define a cavity. The wavelength of laser light from an FP type laser diode is composed of wavelengths of light satisfying Bragg law that is a condition in which the phase of light changes by 2Π (330°) when it travels and returns between both ends of a laser diode chip, within the gain distribution of the laser diode. In general, when the length of a semiconductor laser diode chip is about 300 μm, the gap between allowable wavelengths is about 1.2 nm under Bragg law. Accordingly, many modes having a wavelength gap of 1.2 nm are allowable for an FP emission mode, for a laser diode for optical communication at a band of 1550 nm. The rays of light with wavelengths that coincide with the gain characteristics of a semiconductor are emitted actually in the FP type emission mode in the allowable modes. In general, about ten modes are simultaneously emitted from an FP type laser diode chip. That is, the total linewidth of an FP type laser diode chip is about 5 nm, a half the width of ten emission modes.

Optical wavelength multiplexing communication that simultaneously transmits rays of light with various different wavelengths using one optical fiber has been popularized in recent years. DWDM (Dense Wavelength Division Multiplexing), one of the optical wavelength multiplexing communications sets the gap between communication channels to 2 nm. The half value breadth of the emission mode of the FP type laser diode chip is about 5 nm, so the FP type laser diode chip cannot be used for a light source of the DWDM. A light source for the DWDM requires a mode emitted from a laser diode chip has a very narrow linewidth and a center wavelength of the emission mode to coincide with the center wavelength of channel following the international standard.

As a method of manufacturing a semiconductor laser diode chip having a very small wavelength linewidth, a method of inserting a grating of which the refraction index changes at a very short distance (for example, at a cycle of 250 nm) into a gain medium of a semiconductor laser diode has been used. There is a DFB-LD (Distributed FeedBack Laser Diode), an example of semiconductor laser diodes. Allowable wavelength modes for the DFB-LD should satisfy Bragg law corresponding to a grating period, but the grating period is very short and the gap between wavelengths that satisfies Bragg law at the grating period is 1.500 nm, very large, so only one mode is actually allowed. The linewidth of the one allowable mode has a half value breadth of about 0.1 nm or less, so it satisfies the linewidth of a light source required for DWDM type of communication. However, it is required to adjust the grating period of a semiconductor laser and the refraction index around a waveguide at the level of 1/1000 in order to fit the wavelength of a DFB-LD to the center of a channel, but the effective refraction index of the waveguide depends on various parameters such as its thickness and width, so it is impossible to exactly fit the refraction index and period of the waveguide to the center of a channel. Accordingly, there is a need for a method capable of adjusting a wavelength after manufacturing a semiconductor laser in order to fit the wavelength exactly to the center of the allowable channel in DWDM. In order to satisfy Bragg law in grating distribution, a change in grating period due to thermal expansion or contraction by changes in refraction index and temperature of a medium according to temperature determines a change in temperature of an allowable mode in a DFB-LD. A wavelength change of the allowable mode due to thermal expansion and contraction is about 10 pm/° C. (picometer/° C.) and allows for only a wavelength change of 1.2 nm to a change in temperature of 120° C. However, in order for a DFB-LD make constant output regardless of a temperature change, it is required to change the amount of current supplied to a semiconductor laser diode to offset the gain characteristic according to a change in operation temperature, but the refraction index of a semiconductor medium changes in accordance with the amount of the current supplied to the semiconductor laser, so the effective gap of a grating changes. In general, considering all the parameters in a DFB-LD, a change in wavelength is 80 pm/° C. This level is about eight-time larger and the effect by thermal expansion of the size of a grating.

A wavelength change of 3.2 nm at the maximum can be achieved by adjusting the temperature of a DFB-LD within 40° C. that is a range not largely changing the characteristic of a laser diode, in consideration of the effect, and accordingly, it is possible to adjust a DFB-LD having a wavelength around an allowable channel center so that the wavelength fits to the allowable channel center. However, there are at least tens of allowable channels in DWDM, DFB-LD having different basic emission characteristics are needed as many as the channel to fill all of the allowable channels. However, according to this configuration, the same DFB-LD cannot be used for several channels, so there is a need for a semiconductor laser that can use the same semiconductor chip for several channels of DWDM. A light source satisfying this requirement is called a wavelength tunable laser, in which the tunable width of a wavelength is generally 20 nm or more and it can be simultaneously used for ten channels in DWDM.

A wavelength tunable laser with an external cavity is used for a light source having a wavelength tunable single mode. FIG. 1 is a diagram illustrating the concept of a semiconductor laser with a wavelength tunable external cavity using polymer bragg grating (PBG) of the related art.

Referring to FIG. 1, in a semiconductor laser diode chip 10, nonreflective coating is performed on the front side 11 facing a PBG waveguide 30, which is for preventing a Fabry-Perot mode. High-reflective coating is generally performed on the rear side 12 opposite to the PBG waveguide 30 in the semiconductor laser diode chip 10. Light emitted from the laser diode chip 10 travels into the PBG waveguide 30 through a lens 20. Alternatively, the light emitted from the laser diode chip may be optically coupled to the PBG waveguide 30 by arranging the laser diode chip 10 and the PBG waveguide 30 within several micrometers from each other. A grating 31 in the PBG waveguide selects rays of light satisfying the grating and Bragg conditions, and then feedbacks some of the rays and transmits the other to the outside. Accordingly, light resonates between the PBG waveguide 30 and the reflective surface of the rear side 12 of the semiconductor chip 10, so a laser with an external cavity is achieved. The light fed back to the semiconductor laser diode chip 10 from the grating 31 of the PBG waveguide determines the emission wavelength of the semiconductor laser diode chip 10, such that only the light satisfying the Bragg conditions of the PBG waveguide 30 is emitted from the laser diode chip 10 and the light is discharged outside through the PBG waveguide 30, and thus communication becomes possible. The laser with an external cavity is a system including the semiconductor laser diode chip 10, the lens 20, and the PBG waveguide 30. In the laser, a change in external temperature changes the refraction index of the semiconductor laser diode chip 10, but the wavelength of laser light is selected by the grating 31 of the PBG waveguide 30, so a change in refraction index of the semiconductor laser diode chip 10 cannot change the wavelength of the laser. On the other hand, the wavelength of a laser depends on a change in the effective grating period according to the temperature of the PBG waveguide 30 and an effective grating period depends on the physical period and the effective refraction index of a waveguide. The PBG waveguide is disposed over a thermoelectric element 35 for changing the effective grating period of the PBG waveguide 30. In general, a change in refractive index of polymeric materials is about 3×10⁻⁴/° C. according to a change in external temperature, very larger in comparison to inorganic material such as glass or silicon, so the laser emission wavelength that is determined by the refraction index and grating period of the PBG waveguide changes by 0.3 nm/° C. The PBG waveguide 30 is a part independent from the laser diode chip 10, so a change in temperature of the PBG waveguide 30 does not change the characteristics of the laser diode chip 10 and is used only for adjusting an emission wavelength. However, the grating 31 of the PBG waveguide 30 is usually very long over 3 mm, so the PBG waveguide 30 cannot be mounted on a micro-package such as a TO type package having a diameter of 5.6 mm and a height of 2 to 3 mm. Accordingly, wavelength tunable lasers with a PBG have been manufactured in a butterfly type package or a mini flat type package that can easily receive the structure illustrated in FIG. 1.

However, the price of the housings of butterfly type package is very high, about fifty to eighty thousand won, and the price of the housings of mini flat type packages is also very high, about forty to sixty thousand won, so the packaging method is an economically large burden.

On the other hand, a TO-can type package has been used for packaging a semiconductor laser at a low cost in the related art. FIG. 2 a diagram illustrating in detail a wavelength tunable laser with the PBG illustrated in FIG. 1 which is assembled in a TO-can type package that has been used in the related art illustrates a process in which light emitted from a TO type laser diode chip of the related art is coupled directly to a PBG waveguide.

Referring to FIG. 2, light emitted from the laser diode chip 10 is coupled to the PBG waveguide 30 and light having a wavelength selected by the grating 31 on the waveguide 30 is fed back to the laser diode chip 10, so the wavelength of the laser light emitted from the laser diode chip 10 is locked to the wavelength selected by the grating 31 of the waveguide 30. The waveguide 30 of the PBG changes in characteristics sensitively to temperature, so the laser diode chip 10 and the PBG waveguide 30 may be disposed over a thermoelectric element 200 to change a wavelength regardless of external temperature.

However, according to the related art, a wavelength can be appropriately and effectively selected by a grating of a waveguide only when the waveguide 30 has a length of 3 mm or more. TO-can type packages of the related art usually have a diameter of 6 mm or less and particularly the cap 140 of the TO-can type package, in the related art, has a diameter of about 4 mm. It is preferable that laser light emitted from the PBG waveguide 30 changes the direction by means of a 45-degree reflective mirror 300 from the central axis of the TO-can type package and travels out of the TO-can type package, but it is impossible to change the direction of the laser light emitted from the waveguide 30 with respect to the central axis of the TO-can type package, using the waveguide 30 having a length of 2 mm or more. In particular, when the size of the reflective mirror 300 for reflecting laser light emitted from the waveguide and the length of the laser diode chip 10 is about 0.5 mm, the laser light emitted from the waveguide 30 can be effectively discharged along the central axis of the TO-can type package only when the length of the waveguide 30 in the TO-can type package is 1 mm or less.

Therefore, in the related art, it was impossible to mount a PBG waveguide having a length of 1 mm or more in a To-can type package having a diameter of 6 mm or less. The standard of a TO-can type package having a diameter of 6 mm or less is a necessary condition for an SFP (Small Formfactor Pluggable) type transceiver equipped with a TO-can type photo diode, and a TO-can type package having a diameter of 6 mm or less is required to manufacturing a photo diode that can be mounted on an SFP type transceiver that has been standardized in the related art.

The background of the present invention has been disclosed in Korean Patent No. 10-0547897 (2006.01.23).

### SUMMARY OF THE INVENTION

An aspect of the present invention provides a laser with an external cavity that allows laser light emitted from a optical waveguide in a PBG-typed wavelength tunable laser having a length of 1 mm or more to travel out of a TO-can type package along the central axis of the TO-can type package.

Another aspect of the present invention provides a laser with an external cavity that can stabilize the wavelength of a wavelength tunable laser, using an inclined mirror that partially transmits/reflects light.

In order to achieve the present invention, the optical waveguide of a PBG is not formed straight, but curved in the present invention.

According to an aspect of the present invention, there is provided a laser with an external cavity having a non-straight waveguide that is formed in a TO-can type package, in which a semiconductor laser diode chip and a optical waveguide with a grating are disposed, the wavelength of light from the semiconductor laser is determined by the grating of the waveguide, and an exit surface and an incident surface of the waveguide are formed in the same direction.

The exit surface and the incident surface of the optical waveguide may be formed in a straight line or formed at a predetermined distance from each other in a straight line.

A 45-degree reflective mirror may be disposed in front of the exit surface so that some of or the entire laser light emitted through the exit surface of the optical waveguide exits the TO-can type package.

The light passing through the 45-degree reflective mirror may pass through a wavelength-selective filter, a photodiode that monitors the intensity of light may be disposed in a light path passing through the wavelength-selective filter and the path of the light reflecting from the wavelength-selective filter, and photoelectric currents flowing in the photodiodes that monitor the intensity of light passing through or reflecting from the wavelength-selective filter may be compared to find out the wavelength of the laser light.

The wavelength-selective filter may be an etalon filter or a thin film filter having a feature of monotone increasing or monotone decreasing with the range of desired wavelengths.

A heater for locally adjusting temperature around the grating of the optical waveguide may be further provided.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram illustrating the concept of a semiconductor laser with a wavelength tunable external cavity using polymer bragg grating of the related art;

FIG. 2 a diagram illustrating in detail a process in which light emitted from a TO type laser diode chip of the related art is coupled directly to a PBG waveguide;

FIG. 3 is a diagram illustrating a waveguide with a curved grating according to the present invention;

FIG. 4 is a diagram illustrating an example when a incident surface and exit surface of a waveguide according to the present invention are not arranged in a straight line;

FIG. 5 is a plan view illustrating a TO type package when a incident surface and exit surface of a waveguide according to the present invention are not arranged in a straight line;

FIG. 6 is a diagram illustrating a laser with an external cavity having a curved linear waveguide in which a wavelength stabilizer according to the present invention; and

FIG. 7 is a laser with an external cavity having a curved linear waveguide that can precisely find out the wavelength of laser light in accordance with the present invention.

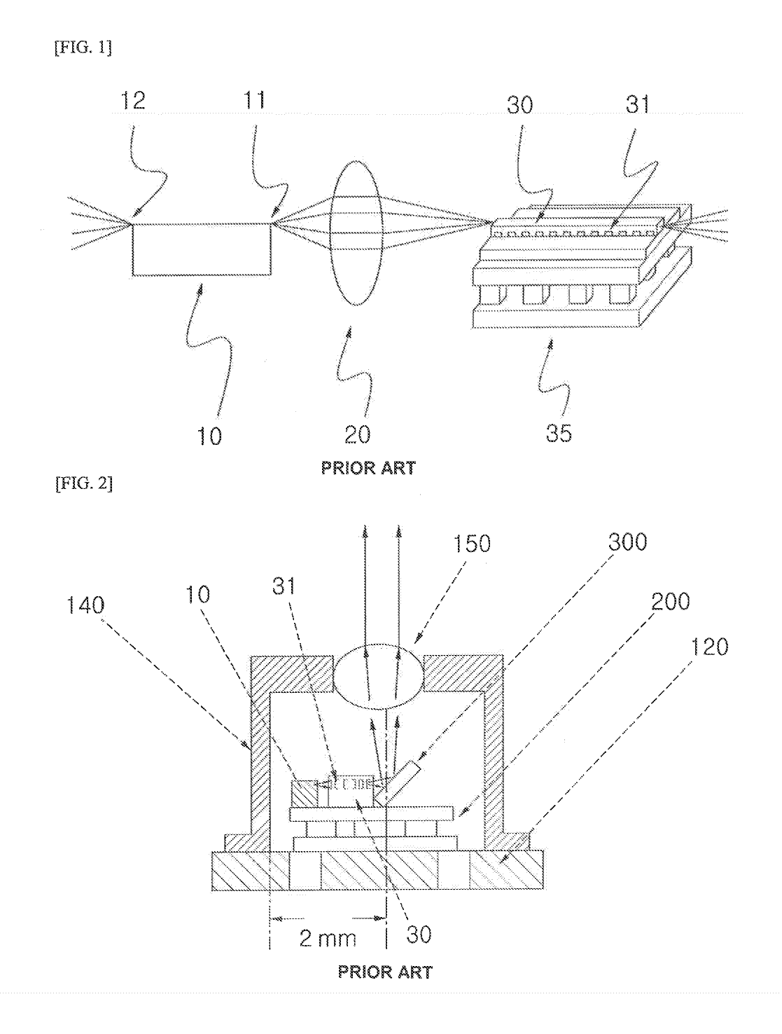

### DETAILED DESCRIPTION OF THE PREFERRED EMBODIMENT

Exemplary embodiments of the present invention will now be described in detail with reference to the accompanying drawings.

Hereinafter, preferred embodiments of the present invention will be described with reference to accompanying drawings.

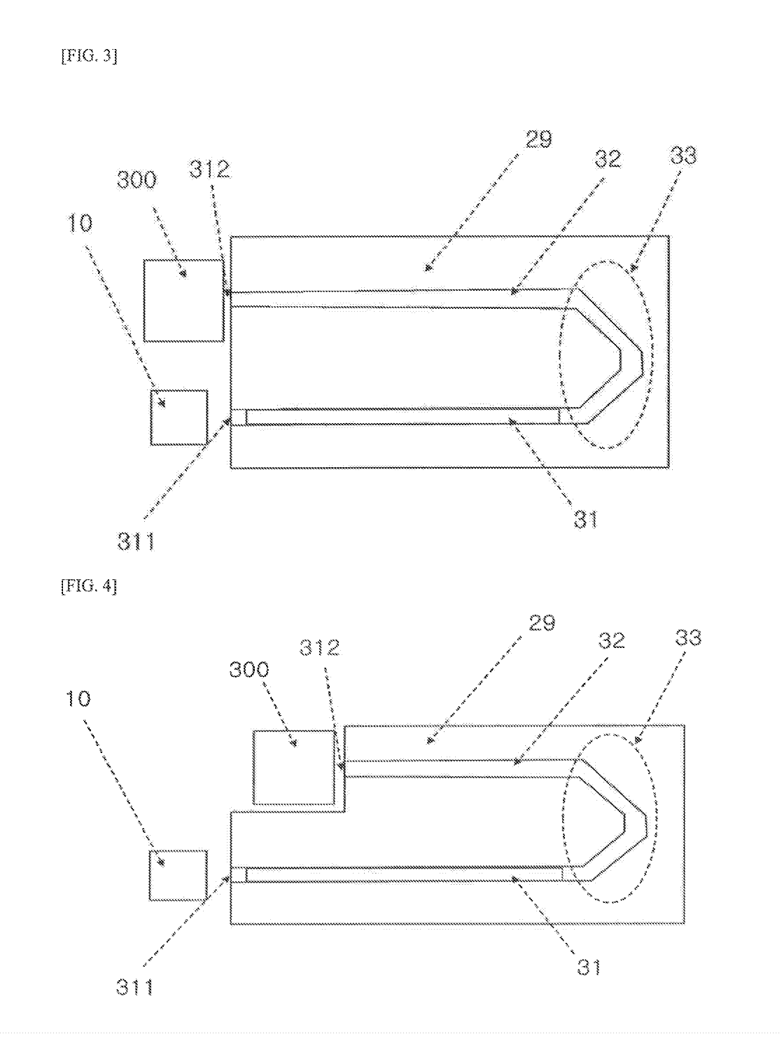

FIG. 3 is a diagram illustrating a waveguide with a curved grating according to an embodiment of the present invention, in which an incident surface 311 and an exit surface 312 of a curved optical waveguide 32 are formed in a straight line. However, there is no reason for arranging the incident surface 311 and the exit surface 312 of a curved optical waveguide 32 in a straight line and the arrangement may be modified in various ways. In FIG. 3, light emitted from the laser diode chip 10 travels inside through the incident surface 311 of the optical waveguide 32. In the rays of light traveling inside through the incident surface 311 of the waveguide, some of the rays of light having a wavelength selected by the grating of the optical waveguide 32 is fed back to the laser diode chip 10, so the laser light emitted from the laser diode chip 10 is locked to the wavelength selected by the grating 31 of the optical waveguide 32. The laser light having the locked wavelength and emitted from the laser diode chip 10 partially reflects from the grating 31 of the optical waveguide 32 and returns to the laser diode chip 10, while the laser light passing through the grating 31 of the optical waveguide 32 travels through the optical waveguide 32 and reaches the curved section 33 of the optical waveguide 32. The optical waveguide 32 is curved at an angle that maintains total reflection of the light traveling in the optical waveguide 32. In general, when the optical wavelength 32 is curved within 45 degrees, the condition for total reflection can be satisfied. In FIG. 3, the optical waveguide 32 changes the direction at 180 degrees, and as a method for the direction change, the waveguide may be bend four times at 45 degrees for total reflection. The optical waveguide 32 may be curved continuously in another direction. In FIG. 3, the laser light traveling to the curved section 33 of the optical waveguide 32 can travel in the waveguide without a loss, with the curved angle of the optical waveguide 32 maintaining the condition for total reflection. In the embodiment illustrated in FIG. 3, laser light travels to the exit surface 312 of the optical waveguide 32 through the straight sections of the waveguide 20 by passing through four portions curved at degrees of the curved section 33 and then exits the optical waveguide 32. In a TO-can type laser package, it is preferable to dispose a reflective mirror 300 having a reflection angle of 45 degrees in front of the exit surface 312 of the optical waveguide 32 so that laser light exits the TO-can type package through a window on the TO-can. That is, in the embodiment illustrated in FIG. 3, the distance between the incident surface 311 and the exit surface 312 of the optical waveguide 32 is not the length of the optical waveguide 32, so it is possible to freely change the length of the optical waveguide 32 even by disposing the exit surface 312 of the optical waveguide 32 close to the central axis of a TO-can type package. Accordingly, an area in which a grating having a sufficient length can be formed is easily ensured on the waveguide 32.

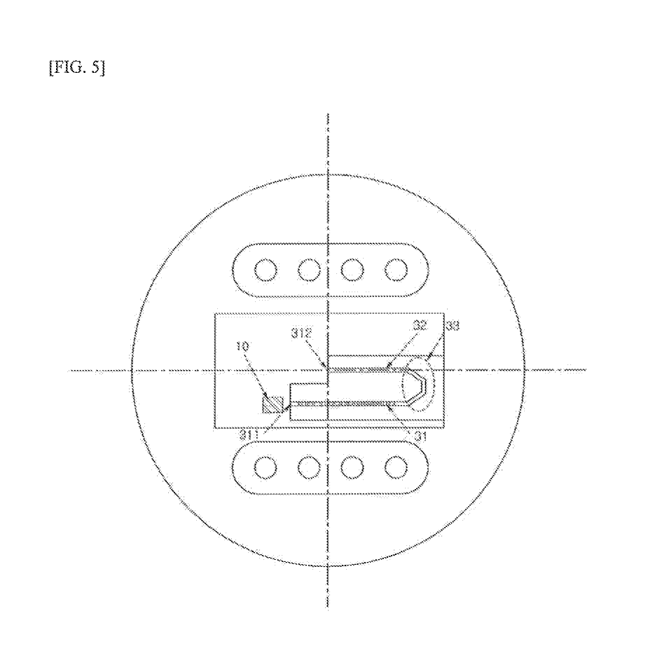

FIG. 4 illustrates an embodiment when an incident surface and exit surface of a waveguide are not disposed in a straight line. Referring to FIG. 4, a portion of a substrate 29 in which the optical waveguide 32 is formed is formed like a step, so the incident surface 311 and the exit surface 312 of the optical waveguide 32 are not arranged in a straight line. According to this configuration, as illustrated in FIG. 5, the exit surface 312 of the optical waveguide 32 can be easily arranged on the central axis of a TO-can type package and the portion where the grating 31 of the optical waveguide 32 can be maximized in the limited inside of the TO-can type stem. In the structure illustrated in FIG. 5, a TO-can type package having a diameter of 6 mm can be used, laser light can exit the optical waveguide 32 along the central axis of the TO-can type package, and a length of 3 mm or more can be ensured for the grating, so a laser with an external cavity can be easily manufactured.

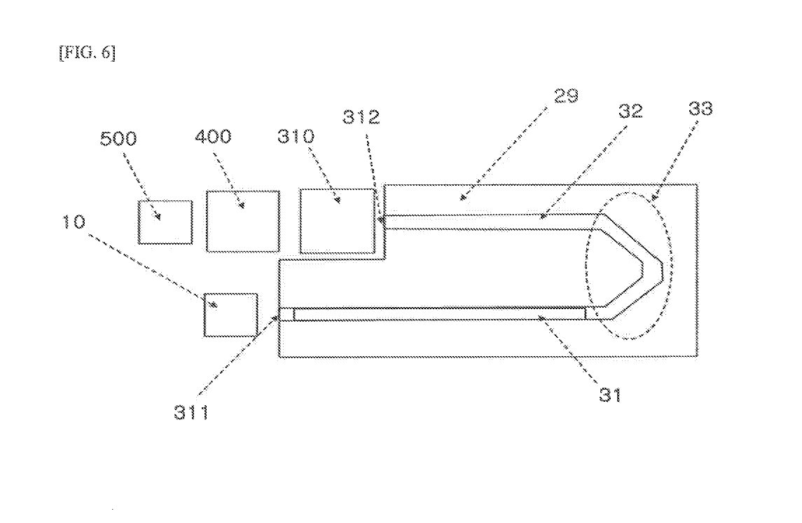

FIG. 6 illustrates a laser with an external cavity having a curved linear waveguide in which a wavelength stabilizer is mounted. Referring to FIG. 6, laser light emitted from the exit surface 312 of the optical waveguide 32 reaches a 45-degree partial reflective mirror 310 having the features of a partial reflective mirror. The ray of light at a predetermined ratio in the laser light reaching the 45-degree partial reflective mirror 310 changes the direction at 90 degrees and exits the TO-can package through a window (not illustrated) on the TO-can type package. The component passing through the 45-degree partial reflective mirror 310 reaches a wavelength-selective filter 400 of which the transmittance/reflection index changes in accordance with a wavelength and the laser light at the ratio passing through the wavelength-selective filter 400 in accordance with its wavelength travels into a photo diode 500 that monitors the intensity of light and generates a photoelectric current, so the wavelength of the laser light can be found out.

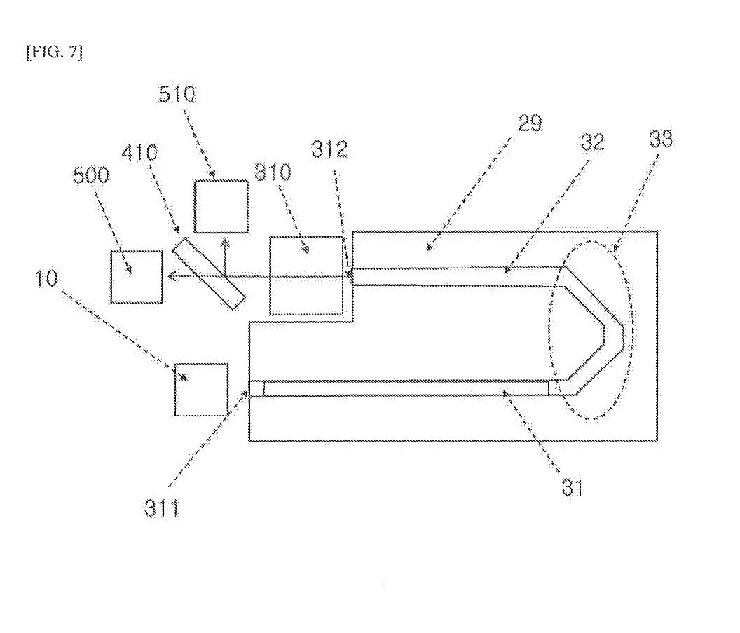

FIG. 7 illustrates a device that can more precisely find out the wavelength of laser light, in which laser light passing through the 45-degree partial reflective mirror 310 reaches the wavelength-selective filter 410 disposed at 45 degrees with respect to the optical axis of laser light. The laser light at a predetermined ratio according to the wavelength of laser light travels to the photodiode 500 that monitors the intensity of light through the wavelength-selective filter 410 and generates a photoelectric current and the laser light reflecting from the wavelength-selective filter 410 travels into another photodiode 510 that monitors the intensity of light and generates a photoelectric current. Accordingly, it is possible to precisely measure the wavelength of light by comparing the amount of currents flowing in the photodiodes 500 and 510 that monitor the intensity of light. In the present invention, the wavelength-selective filter 410 can be manufactured in various ways and one available method is to use an etalon filter. Another method is to use a thin film filter using a thin dielectric film, in which the thin film filter preferably has a feature of monotone increasing or monotone decreasing within a range of desired wavelengths.

According to this structure of the present invention, it is possible to manufacture a laser with an external cavity that is not expensive, using a cheap TO-can type package. Further, it is possible to form a waveguide type of external cavity in a TO-can type package of which the diameter is limited to 6 mm or less such that the length of the waveguide with a grating can be maximized and laser light coming out of the waveguide can exit the TO-can type package along the central axis of the TO-can type package. Further, according to the present invention, it is possible to effectively dispose a wavelength stabilizer that can monitor the wavelength of laser light in a laser with an external cavity having a non-straight wavelength.

On the other hand, it is preferable that the laser diode chip 10 and the optical waveguide 32 are disposed over a thermoelectric element in the present invention, and this is for preventing a change in external temperature from influencing the cavity of the laser. Further, it is preferable that the optical waveguide 32 of the present invention is a polymer waveguide using a polymer, in order to use the feature of the polymer waveguide of which the refractive index greatly changes in accordance with temperature in a wavelength tunable laser that is a main modification of the present invention. In particular, in order to manufacture a laser with a wavelength-tunable external cavity, it is required to change the temperature around the gating 31 in the polymer waveguide and it may be achieved by adjusting the temperature around the grating of the waveguide, using a specific heater.

As set forth above, according to exemplary embodiments of the invention, the waveguide is curved, so the lengths of straight waveguides of the related art are determined as the distance between the incident portion and the exit portion, whereas the length of the curved waveguide is irrelevant to the positions of the incident portion and the exit portion, such that the length of the wavelength can be determined regardless of the positions of the incident portion and the exit portion. Accordingly, the waveguide can have a length of 1 mm or more and can be disposed with the exit portion close to the central axis of the package. Therefore, it is possible to easily manufacture the laser with an external cavity having a waveguide with a grating using a TO-can type package.

While the present invention has been illustrated and described in connection with the exemplary embodiments, it will be apparent to those skilled in the art that modifications and variations can be made without departing from the spirit and scope of the invention as defined by the appended claims.

What is claimed is:

1. A laser with an external cavity having a non-straight waveguide that is formed in a TO-can type package, wherein a semiconductor laser diode chip and a optical waveguide with a grating are disposed, the optical wavelength of light from the semiconductor laser is determined by the grating of the optical waveguide, and an exit surface and an incident surface of the optical waveguide are formed in the same direction.

2. The laser of claim 1, wherein the exit surface and the incident surface of the optical waveguide are formed in a straight line.

3. The laser of claim 1, wherein the exit surface and the incident surface of the optical waveguide are formed at a predetermined distance from each other in a straight line.

4. The laser of claim 1, wherein a 45-degree reflective mirror is disposed in front of the exit surface so that some of or the entire laser light emitted through the exit surface of the optical waveguide exits the TO-can type package.

5. The laser of claim 4, wherein the light passing through the 45-degree reflective mirror passes through a wavelength-selective filter, a photodiode that monitors the intensity of light is disposed in a light path passing through the wavelength-selective filter and the path of the light reflecting from the wavelength-selective filter, and photoelectric currents flowing in the photodiodes that monitor the intensity of light passing through or reflecting from the wavelength-selective filter are compared to find out the wavelength of the laser light.

6. The laser of claim 5, wherein the wavelength-selective filter is an etalon filter.

7. The laser of claim 5, wherein the wavelength-selective filter is a thin film filter having a feature of monotone increasing or monotone decreasing with the range of desired wavelengths.

8. The laser of claim 1, wherein a heater for locally adjusting temperature around the grating of the optical waveguide is further provided.
